(19) United States
(12) Patent Application Publication
(10) Pub. No.: US 2009/0219076 A1
(43) Pub. Date: Sep. 3, 2009

(54) APPARATUS, SYSTEM, AND METHOD FOR GROUNDING INTEGRATED CIRCUIT OUTPUTS

(76) Inventor: Wenwei Wang, Gilroy, CA (US)

Correspondence Address: Kunzler & McKenzie, 8 EAST BROADWAY, SUITE 600, SALT LAKE CITY, UT, 84111, US

(21) Appl. No.: 12/039,580

(22) Filed: Feb. 28, 2008

(51) Int. Cl. H03K 17/687

(52) U.S. Cl. 327/427

(57) ABSTRACT

An apparatus, system, and method are disclosed for grounding IC outputs. A first switching module turns on when an IC power supply voltage exceeds a base voltage. The first switching module is in communication with IC outputs and a common ground. The IC outputs are configured to be pulled up to the IC power supply voltage through pull-up resistors when a first voltage is driven lower than the base voltage. In addition, the first switching module connects the IC outputs to the common ground. A second switching module turns on, turns turn off the first switching module, disconnects the IC outputs from the common ground, and pulls the IC outputs up to the IC power supply voltage when the IC power supply voltage exceeds a minimum working voltage.

### BACKGROUND OF THE INVENTION

1. Field of the Invention

This invention relates to grounding outputs and more particularly relates to grounding integrated circuit outputs.

2. Description of the Related Art

Digital integrated circuits (ICs) communicate by driving signal lines to either a high value or to a low value. For example, driving a signal line to three point three volts (3.3 V) may assert the signal line while driving the signal line to zero volts (0 V) may de-assert the signal line.

An IC output drives each signal line. An IC input is driven by the signal line. The IC inputs distinguish the high value and the low value by comparing a signal line voltage to a power supply voltage. If the signal line voltage is within a specified range of the power supply voltage, the IC input may determine that the signal line has the high value.

Each IC output drives the signal line to a low value such as zero volts (0 V). In addition an IC output may drive the signal line to the high value. The high value may be within the specified range of the power supply voltage.

When the IC is powered on or powered off, the power supply voltage is indeterminate for a brief period. During that period, the IC outputs may appear to drive the signal lines to unintended bull and/or high values. For example, the IC output may be interpreted by the IC input as asserting the signal line. The unintentional assertion of the signal line may put a system in an uncertain state.

### SUMMARY OF THE INVENTION

From the foregoing discussion, there is a need for an apparatus, system, and method for grounding IC outputs. Beneficially, such an apparatus, system, and method would ground IC outputs and prevent unintentional assertion of a signal line that may place a system in an uncertain state.

The present invention has been developed in response to the present state of the art, and in particular, in response to the problems and needs in the art that have not yet been fully solved by currently available IC grounding methods. Accordingly, the present invention has been developed to provide an apparatus, system, and method for grounding IC outputs that overcome many or all of the above-discussed shortcomings in the art.

The apparatus to ground IC outputs is provided with a plurality of modules configured to functionally execute the steps of turning on a first switching module, connecting IC outputs, turning on a second switching module, turning off the first switching module, and disconnecting the IC outputs. These modules in the described embodiments include a first switching module and a second switching module.

The first switching module is in communication with IC outputs and a common ground. The first switching module is configured to turn on and connect the IC outputs to the common ground when an IC power supply voltage exceeds a base voltage. The IC outputs are pulled up to the IC power supply voltage through pull-up resistors when a first voltage is driven lower than the base voltage. The second switching module is configured to turn off the first switching module, disconnect the IC outputs from the common ground, and pull the IC outputs up to the IC power supply voltage when the IC power supply voltage exceeds a minimum working voltage.

A system of the present invention is also presented for grounding IC outputs. In particular, the system, in one embodiment, includes an IC power supply, a plurality of IC outputs, a common ground, a first switching module, and a second switching module.

The first switching module is in communication with IC outputs and a common ground. The first switching module is configured to turn on and connect the IC outputs to the common ground when an IC power supply voltage exceeds a base voltage. The IC outputs are pulled up to the IC power supply voltage through pull-up resistors when a first voltage is driven lower than the base voltage. The first switching module comprises a first voltage divider and a low voltage first FET. The first voltage divider is in communication with the IC power supply and the common ground. The first voltage divider yields the first voltage that is a specified fraction of the IC power supply voltage at a first divider output.

A source of the first FET is in communication with the IC outputs and with the IC power supply through a first resistor, a drain of the first FET is in communication with the common ground, and a gate of the first FET is in communication with the first divider output. The first FET turns on when the first voltage exceeds the base voltage. The second switching module is configured to turn off the first switching module, disconnect the IC outputs from the common ground, and pull the IC outputs up to the IC power supply voltage when the IC power supply voltage exceeds a minimum working voltage.

A method of the present invention is also presented for grounding IC outputs. The method in the disclosed embodiments substantially includes the steps to carry out the functions presented above with respect to the operation of the described apparatus and system. In one embodiment, the method includes turning on a first switching module, connecting IC outputs, turning on a second switching module, turning off the first switching module, and disconnecting the IC outputs.

A first switching module turns on when an IC power supply voltage exceeds a base voltage. The first switching module is in communication with IC outputs and a common ground. The IC outputs are configured to be pulled up to the IC power supply voltage through pull-up resistors when a first voltage is driven lower than the base voltage. In addition, the first switching module connects the IC outputs to the common ground. A second switching module turns on, turns turn off the first switching module, disconnects the IC outputs from the common ground, and pulls the IC outputs up to the IC power supply voltage when the IC power supply voltage exceeds a minimum working voltage.

References throughout this specification to features, advantages, or similar language do not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention may be practiced without one or more of the specific features or advantages of a particular embodiment. In other instances, additional features and advantages may be recognized in certain embodiments that may not be present in all embodiments of the invention.

The present invention provides an apparatus, system, and method for grounding IC outputs. Beneficially, such an apparatus, system, and method would allow grounding IC outputs when an IC is powered on or powered off. The present invention may protect an IC from entering an uncertain state due to unintentional assertion of signal lines. These features and advantages of the present invention will become more fully apparent from the following description and appended claims, or may be learned by the practice of the invention as set forth hereinafter.

### BRIEF DESCRIPTION OF THE DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1 is a schematic circuit diagram illustrating one embodiment of a system for grounding IC outputs in accordance with the present invention;

FIG. 2 is a schematic circuit diagram illustrating another embodiment of the system for grounding IC outputs in accordance with the present invention;

FIG. 3 is a schematic circuit diagram illustrating one more embodiment of the system for grounding IC outputs of the present invention;

FIG. 4 is a schematic circuit diagram illustrating an alternative embodiment of the system for grounding IC outputs of the present invention;

FIG. 5 is a schematic flow chart diagram illustrating one embodiment of a method for grounding IC outputs of the present invention; and

FIG. 6 is a graph illustrating one embodiment of an IC power supply voltage and an IC output voltage of the present invention.

### DETAILED DESCRIPTION OF THE INVENTION

Many of the functional units described in this specification have been labeled as modules, in order to more particularly emphasize their implementation independence. Modules may include hardware circuits such as one or more processors with memory, Very Large Scale Integration (VLSI) circuits, gate arrays, programmable logic, and/or discrete components. The hardware circuits may perform hardwired logic functions, execute computer readable programs stored on tangible storage devices, and/or execute programmed functions. The computer readable programs may in combination with a computer system perform the functions of the invention.

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art will recognize, however, that the invention may be practiced without one or more of the specific details, or with other methods, components, materials, and so forth. In other instances, well-known structures, materials, or operations are not shown or described in detail to avoid obscuring aspects of the invention.

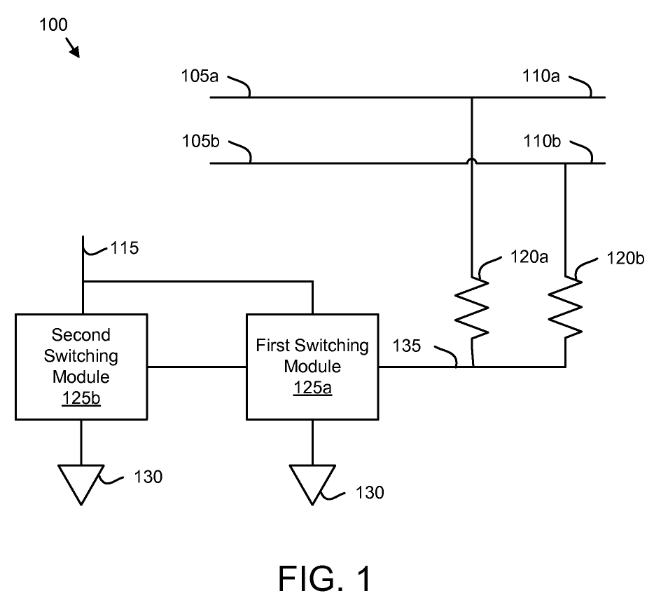

FIG. 1 is a schematic circuit diagram illustrating one embodiment of a system 100 for grounding IC outputs of the present invention. The system 100 includes a plurality of IC signals 105a-b, a plurality of IC outputs 110a-b, an IC power supply 115, a plurality of pull-up resistors 120a-b, a first switching module 125a, a second switching module 125b, a plurality of common grounds 130, and a pull-up line 135. Although for simplicity, only two (2) IC signals 105a-b, two (2) IC outputs 110a-b, one IC power supply 115, two (2) pull-up resistors 120a-b, one first switching module 125a, one second switching module 125b, two (2) common grounds 130, and one pull-up line 135 are shown, any number may be employed in the system 100.

The IC power supply 115 may provide current at a power supply voltage for proper functioning of a plurality of digital ICs communicating over a plurality of bi-directional signal lines. The signal lines may be configured as clock lines and/or data lines. For example, the IC power supply 115 may provide the current at the power supply voltage of five volts (5V).

The plurality of pull-up resistors 120a-b may be fabricated within an IC. Alternatively, the pull-up resistors 120a-b may be configured as discrete electronics mounted on the same circuit board such as of the plurality of ICs, the first and second switching modules 125a-b, and the like. Each pull-up resistor 120a-b may have a resistance of in the range of one thousand to five thousand ohms (1000-5000Ω) depending on a requirement to provide a required logic level current over an operating range of temperature and an operating range of power supply voltage.

The plurality of pull-up resistors 120a-b may be used to ensure that the plurality of IC outputs 110a-b may settle at expected logic levels when the IC signals 105a-b are driven high. The plurality of IC signals 105a-b may be driven by semiconductor logic within an IC.

The plurality of IC outputs 110a-b may drive each signal line. For example, each IC output 110a-b may drive the signal line to a low value such as zero volts (0 V). In addition each IC output 110a-b may drive the signal line to a high value. The high value may be within a specified range of the power supply voltage. Continuing with the example, driving the signal line to a signal line voltage of the value of three point three volts (3.3 V) may assert the signal line while driving the signal line to the signal line voltage of the value of zero volts (0 V) may de-assert the signal line.

The IC power supply voltage may ramp up or ramp down for a brief period of time when the IC is powered on or powered off respectively. The IC outputs 110a-b may also follow same behavior through their corresponding pull-up resistors 120a-b for the same brief period of time. For example, the IC output 110a may ramp up through the corresponding pull-up resistor 120a till the power supply voltage reaches the signal line voltage of the value of four point seven five volts (4.75 V).

The first switching module 125a is in communication with the IC outputs 110a-b and the common ground 130. The first switching module 125a is also in communication with the IC power supply 115. The second switching module 125b is shown in communication with the IC power supply 115, the first switching module 125a, and the common ground 130. The plurality of common grounds 130 may pull the electrical potential of the plurality of IC outputs 110a-b to zero volts (0 V). The common ground 130 may be an electrically common point as is well known to those of skill in the art.

In one embodiment of the present invention, the first and second switching modules 125a-b comprise semiconductor structures integrated in a semiconductor device. The first and second switching modules 125a-b may be configured by a method as is well known to those of skill in the art.

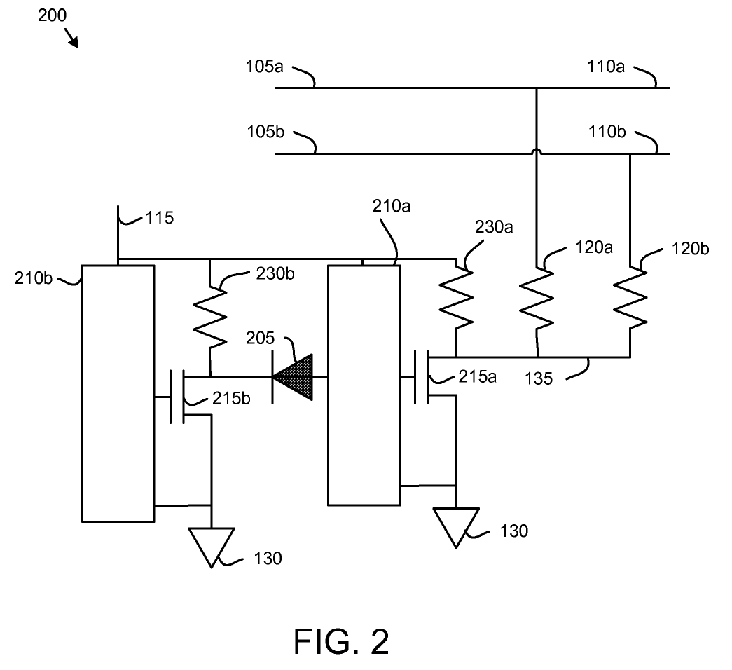

FIG. 2 is a schematic circuit diagram illustrating another embodiment of the system 200 for grounding IC outputs of the present invention. The description of system 200 refers to elements of FIG. 1, like numbers referring to like elements. The system 200 includes a diode 205, a first voltage divider 210a, a second voltage divider 210b, a low voltage first field effect transistor (FET) 215a, a low voltage second FET 215b, a first resistor 230a, a second resistor 230b, the plurality of IC signals 105a-b, the plurality of IC outputs 110a-b, the IC power supply 115, the plurality of pull-up resistors 120a-b, the plurality of common grounds 130, and the pull-up line 135. Although for simplicity, only one diode 205, one first voltage divider 210a, one second voltage divider 210b, one low voltage first FET 215a, one low voltage second FET 215b, one first resistor 230a, one second resistor 230b, two (2) IC signals 105a-b, two (2) plurality of IC outputs 110a-b, one IC power supply 115, two (2) plurality of pull-up resistors 120a-b, two (2) common grounds 130, and one pull-up line 135 are shown, any number may be employed in the system 200.

The first and second FETs 215a-b may comprise a source terminal, a gate terminal, a body terminal, and a drain terminal. The first and second FETs 215a-b may be constructed from a number of semiconductor materials selected from silicon oxide, germanium oxide, or the like. The first and second FETs 215a-b may be selected from a Metal-Oxide-Semiconductor FET (MOSFET), Junction FET (JFET), Modulation Doped FET, insulated-gate bipolar transistor, or the like.

Each first and second FETs 215a-b may be configured as a P-type or a N-type FET. A low voltage power supply on the gate terminal of the first and second FETs 215a-b configured as P-type MOSFET may create a P-type conducting channel that may allow to conduct a current from the source terminal to the drain terminal. A high voltage power supply on the gate terminal of the first and second FETs 215a-b configured as N-type MOSFET may create a N-type conducting channel that may allow to conduct a current from the source terminal to the drain terminal.

The first and second FETs 215a-b may function either in an enhancement-mode, a depletion-mode, or a combination thereof. The first and/or second FET 215a-b functioning in the depletion-mode may be so doped that there may exist the conducting channel with a very low power supply voltage for example, of the value of zero point zero zero five volts (0.005 V) from the gate terminal to the source terminal. The first and second voltage dividers 210a-b may divide the power supply voltage to a specified value. Each voltage divider 210a-b may comprise one or more resistors in series that provide a specified fraction of the power supply voltage. For example, the first voltage divider 210a may supply one tenth ( 1/10^{th}) of the power supply voltage at the gate terminal of the first FET 215a while the second voltage divider 210b supplies one half of the power supply voltage at the gate terminal of the second FET 215b.

The first FET 215a and the second FET 215b are shown electronically connected through the diode 205. The diode 205 may be selected from a P-type or a N-type diode. The first FET 215a is shown connected to the IC power supply 115 through the first resistor 230a and the common ground 130. The second FET 215b is shown connected to the power supply through the second resistor 230b and the common ground 130.

The first voltage divider 210a and the first FET 215a may constitute the first switching module 125a. The second voltage divider 210b and the second FET 215b may constitute the second switching module 125b. The first switching module 125a and the second switching module 125b may constitute an apparatus for grounding IC outputs 110a-b.

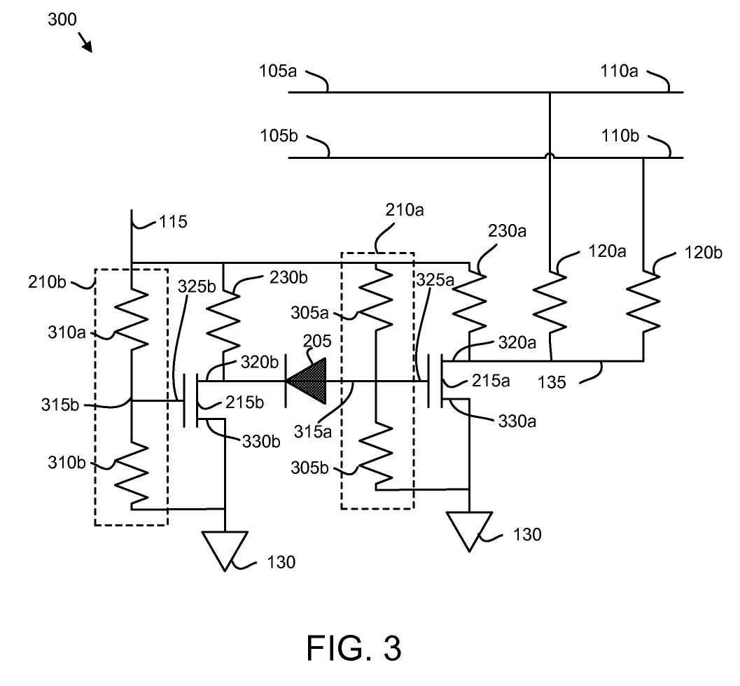

FIG. 3 is a schematic circuit diagram illustrating one more embodiment of the system 300 for grounding IC outputs of the present invention. The description of system 300 refers to elements of FIGS. 1-2, like numbers referring to like elements. The system 300 includes the diode 205, the first voltage divider 210a, the second voltage divider 210b, the first FET 215a, the second FET 215b, the first resistor 230a, the second resistor 230b, the plurality of IC signals 105a-b, the plurality of IC outputs 110a-b, the IC power supply 115, the plurality of pull-up resistors 120a-b, the plurality of common grounds 130, a first divider output 315a, a second divider output 315b, and the pull-up line 135. Although for simplicity, only one diode 205, one first voltage divider 210a, one second voltage divider 210b, one first FET 215a, one second FET 215b, one first resistor 230a, one second resistor 230b, two (2) IC signals 105a-b, two (2) plurality of IC outputs 110a-b, one IC power supply 115, two (2) plurality of pull-up resistors 120a-b, two (2) common grounds 130, one first divider output 315a, one second divider output 315b, and one pull-up line 135 are shown, any number may be employed in the system 300.

The first FET 215a includes a gate 325a, a source 320a, and a drain 330a. The second FET 215b includes a gate 325b, a source 320b, and a drain 330b. The first voltage divider 210a includes a plurality of resistors 305a-b. Although for simplicity, only, two (2) resistors 305a-b are shown, any number may be employed in the first voltage divider 210a. The second divider 210b also includes a plurality of resistors 310a-b. Although for simplicity, only, two (2) resistors 310a-b are shown, any number may be employed in the second voltage divider 210b.

The IC power supply 115 may provide current at a power supply voltage for proper functioning of the plurality of digital ICs. The first switching module 125a turns on and connects the IC outputs 110a-b to the common ground 130 when the IC power supply voltage exceeds a base voltage.

In one embodiment, the base voltage is in the range of one percent (1%) to five percent (5%) of a nominal power supply voltage. The nominal power supply voltage may be in the range of minus ten percent (−10%) to plus ten percent (+10%) of a target voltage selected from one point zero volts (1.0 V), one point eight volts (1.8 V), and three point three volts (3.3 V). Alternatively, the nominal power supply voltage may be in the range of minus five percent (−5%) to plus five percent (+5%) of the target voltage.

For example, the nominal power supply voltage may vary from zero point nine volts (0.9 V) to one point one volts (1.1 V) when the target voltage is selected of the value of one point zero volts (1.0 V). In another example, the nominal power supply voltage may vary from one point seven one volts (1.71 V) to one point eight nine volts (1.89 V) when the target voltage is selected of the value of one point eight volts (1.8 V). In one more example, the nominal power supply voltage may vary from three point one three five volts (3.135 V) to three point four three five volts (3.435 V) when the target voltage is selected of the value of three point three volts (3.3 V).

Continuing with the examples above, the base voltage may vary from zero point zero zero nine volts (0.009 V) to zero point zero five five volts (0.055 V) when the target voltage is one point zero volts (1.0 V). The base voltage may vary from zero point zero one six two volts (0.0162 V) to zero point zero nine nine volts (0.099 V) when the target voltage is one point eight volts (1.8 V). The base voltage may vary from zero point zero three volts (0.03 V) to zero point one eight volts (0.18 V) when the target voltage is three point three volts (3.3 V).

The first switching module 125a comprises the first voltage divider 210a and the first FET 215a. The first voltage divider 210a is in communication with the IC power supply 115 and the common ground 130. The first voltage divider 210a yields a first voltage that is a specified fraction of the IC power supply voltage at the first divider output 315a. For example, the first voltage divider 210a may yield the first voltage of the value of zero point one nine volts (0.19 V) at the first divider output 315a.

The IC outputs 110a-b are configured to be pulled up to the IC power supply voltage through pull-up resistors 120a-b when the first voltage is driven lower than the base voltage. For example, the IC outputs 110a-b may be pulled up to the IC power supply voltage through pull-up resistors 120a-b when the first voltage of the value of zero point one nine volts (0.19 V) at the first divider output 315a is driven lower than the base voltage of the value of zero point one nine five volts (0.195 V).

The source 320a of the first FET 215a is in communication with the IC outputs 110a-b. The first FET 215a is in communication with the IC power supply 115 through the first resistor 230a. The drain 330a of the first FET 215a is in communication with the common ground 130. The gate 325a of the first FET 215a is in communication with the first divider output 315a.

The IC outputs 110a-b are configured to be pulled up to the IC power supply voltage through pull-up resistors 120a-b when the first voltage is driven lower than the base voltage. For example, the IC outputs 110a-b may be pulled up to the IC power supply voltage through pull-up resistors 120a-b when the first voltage of the value of zero point one nine volts (0.19 V) is driven lower than the base voltage of the value of zero point one nine five volts (0.195 V).

The second switching module 125b turns off the first switching module 125a, disconnects the IC outputs 110a-b from the common ground 130, and pulls the IC outputs 110a-b up to the IC power supply voltage when the IC power supply voltage exceeds the minimum working voltage. The minimum voltage may be in the range of eighty five percent (85%) to ninety five percent (95%) of the nominal power supply voltage. For example, the minimum voltage may vary from zero point seven seven volts (0.77 V) to one point zero five volts (1.05 V) when the target voltage is one point zero volts (1.0 V). In other example, the minimum voltage may vary from one point three eight volts (1.38 V) to one point eight eight volts (1.88 V) when the target voltage is one point eight volts (1.8 V). In one more example, the minimum voltage may vary from two point five two volts (2.52 V) to three point four five volts (3.45 V) when the target voltage is three point three volts (3.3 V).

In an embodiment, the second switching module 125b comprises the second voltage divider 210b and the second FET 215b. The second voltage divider 210b may be in communication with the IC power supply 115 and the common ground 130. The second voltage divider 210b may yield a second voltage that is a specified fraction of the power supply voltage at a second divider output 315b. For example, the second voltage divider 210b may yield the second voltage of the value of one volt (1 V) at the second divider output 315b.

In an embodiment, the source of the 320b of the second FET 215b is in communication with the IC power supply 115 through the second resistor 230b. The source 320b of the second FET 215b may be in further communication with the gate 325a of the first FET 215a through the diode 205. The drain 330b of the second FET 215b may be in communication with the common ground 130. The gate 325b of the second FET 215b may be in communication with the second voltage divider output 315b. The second FET 215b may turn on when the second voltage exceeds the minimum working voltage and further may turn off the first switching module 125a.

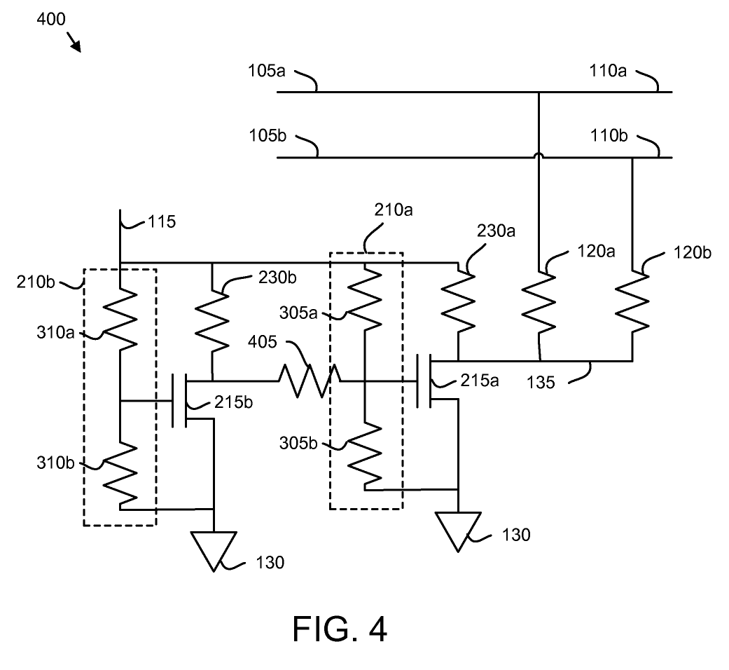

FIG. 4 is a schematic circuit diagram illustrating an alternative embodiment of the system 400 for grounding IC outputs of the present invention. The description of system 400 refers to elements of FIGS. 1-3, like numbers referring to like elements. The system 400 includes a connecting resistor 405, the first FET 215a, the second FET 215b, the first resistor 230a, the second resistor 230b, the plurality of IC signals 105a-b, the plurality of IC outputs 110a-b, the IC power supply 115, the plurality of pull-up resistors 120a-b, the plurality of common grounds 130, the first divider output 315a, the second divider output 315b, and the pull-up line 135. Although for simplicity, only one connecting resistor 405, one first FET 215a, one second FET 215b, one first resistor 230a, one second resistor 230b, two (2) IC signals 105a-b, two (2) plurality of IC outputs 110a-b, one IC power supply 115, two (2) plurality of pull-up resistors 120a-b, one first switching module 125a, one second switching module 125b, two (2) common grounds 130, one first divider output 315a, one second divider output 315b, and one pull-up line 135 are shown, any number may be employed in the system 200.

In the shown embodiment, the connecting resistor 405 connects the first divider output 315a and the source 320b of the second FET 215b. The connecting resistor 405 may control communication between the gate 325a of the first FET 215a and the source 320b of the second FET 215b. The resistance of the connecting resistor 405 may be selected in such a way that the connecting resistor 405 may allow flow of current if there exist an electrical potential of at least for example, one point five volts (1.5 V). For example, the connecting resistor 405 with resistance of the value of one-kilo ohm (1 KΩ) that may allow the current to pass when the electrical potential between the second divider output 315b and the first divider output 315a is of the value of one point five eight volts (1.8 V).

The schematic flow chart diagram that follows is generally set forth as logical flow chart diagram. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

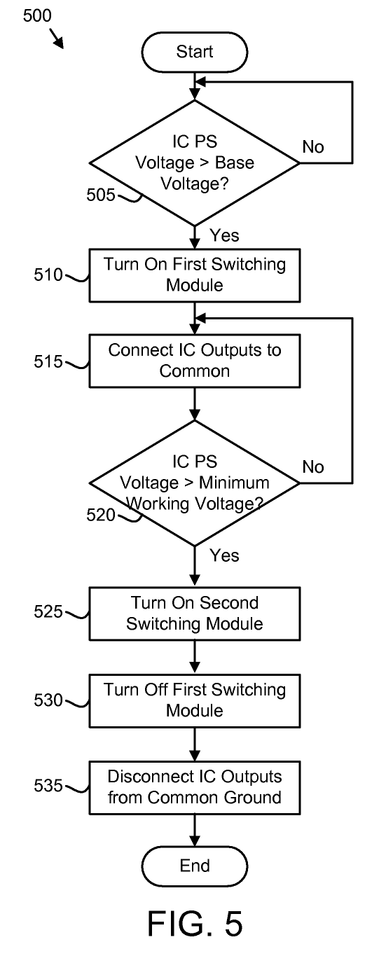

FIG. 5 is a schematic flow chart diagram illustrating one embodiment of a method 500 for grounding IC outputs in accordance with the present invention. The method 500 substantially includes the steps to carry out the functions presented above with respect to the operation of the described systems 100, 200, 300, and 400 of FIGS. 1-4. The description of the method 400 refers to elements of FIGS. 1-4, like numbers referring to like elements.

The method 500 begins, and in an embodiment, a first switching module 125a turns on 510 when the IC power supply voltage exceeds 505 the base voltage. In an embodiment, the base voltage is in the range of 1% to 5% of the nominal power supply voltage. For example, the first switching module 125a may automatically detect 505 the IC power supply voltage of the value of zero point one seven one volts (0.171 V) greater than the base voltage of the value of zero point one seven zero five volts (0.1705 V).

If the IC power supply voltage is not greater than the base voltage the first switching module 125a may further detect 505 the IC power supply voltage greater than the base voltage. If the first switching module 125a detects 505 that the IC power supply voltage is greater than the base voltage the first switching module 125a turns on 510. For example, a conductive channel may be automatically established between the source 320a and the drain 330a of the first FET 215a to turn on 510 the first switching module 125a when the IC power supply voltage of the value of zero point one seven one volts (0.171 V) is greater than the base voltage of the value of zero point one seven zero five volts (0.1705 V).

The first switching module 125a connects 515 the IC outputs 110a-b to the common ground 130. The connection of the IC outputs 110a-b to the common ground 130 may result connection of each pull-up resistor 120a-b switched from the power supply voltage to the common ground 130. For example, the first switching module 125a may connect 515 the each IC output 110a-b to the common ground 130.

The first switching module 125a may further detect 520 the IC power supply voltage greater than the minimum working voltage. For example, the first switching module 125a may automatically detect 520 the IC power supply voltage greater than the minimum working voltage or not.

In an embodiment, the minimum voltage is in the range of 85% to 95% of a nominal power supply voltage. For example, the first switching module 125a may automatically detect 520 the IC power supply voltage of the value of three point two five volts (3.25 V) greater than the minimum working voltage of the value of three point two volts (3.2 V).

If the first switching module 125a detects 520 that the IC power supply voltage is not greater than the minimum working voltage the first switching module 125a may connect 515 the IC outputs 110a-b to the common ground 130. If the first switching module 125a detects 520 that the IC power supply voltage is greater than the minimum working voltage, the second switching module 125b turns on 525. For example, a conductive channel may be automatically established between the source 320b and the drain 330b of the second FET 215b to turn on 525 the second switching module 125b when the IC power supply voltage of the value of three point two five volts (3.25 V) is greater than the minimum working voltage of the value of three point two volts (3.2 V).

The second switching module 125b turns off 530 the first switching module 125a. For example, the second switching module 125b may automatically connect the gate 325a of the first FET 215a to ground 130 through the diode 205 or the connecting resistor 405 to turn off 530 the first switching module 125a.

The second switching module 125b disconnects the IC outputs 110a-b from the common ground 130 and pulls the IC outputs up to the IC power supply voltage. For example, the second switching module 125b may automatically disconnect the IC outputs 110a-b from the common ground 130 and may further pull the IC outputs 110 up to the IC power supply voltage of the value of three point two volts (3.2 V). Thus the method 500 would automatically ground IC outputs 110a-b when the power supply voltage is less than the base voltage. Additionally, the method 500 would pull up the IC outputs 110a-b to the power supply voltage when the power supply voltage is greater than the minimum working voltage.

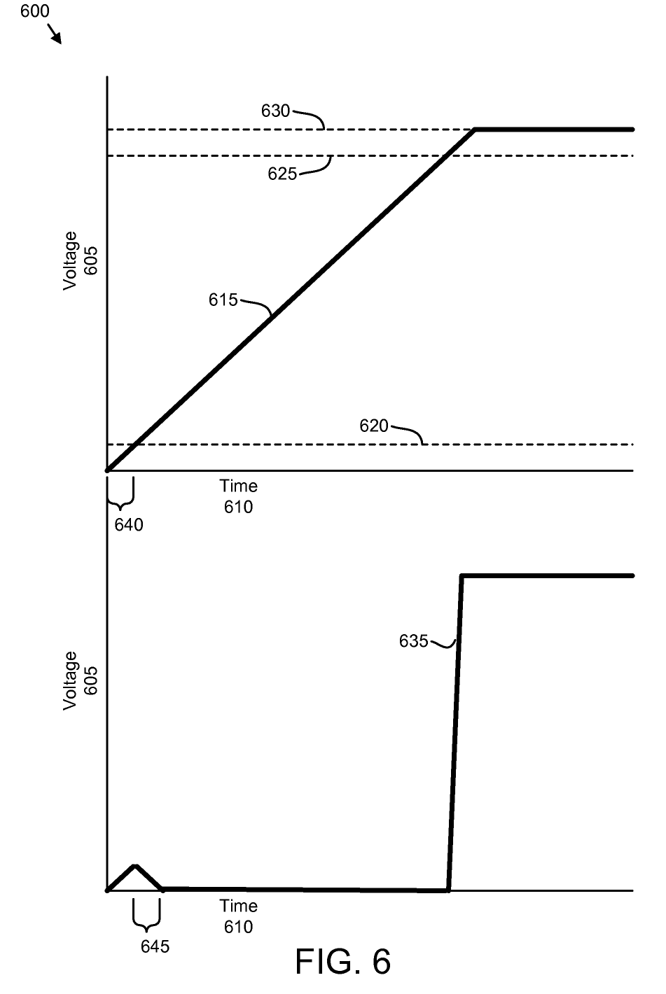

FIG. 6 is a graph 600 illustrating one embodiment of an IC power supply voltage 615 and an IC output voltage 635 of the present invention. The graph 600 is a prophetic example. The description of graph 600 refers to elements of FIGS. 1-5, like numbers referring to like elements. The graph includes a minimum working voltage 625, a target voltage 630, and a base voltage 620.

In the shown embodiment, the graph 600 for the IC power supply voltage 615 and the IC output voltage 635 is drawn with voltage 605 along a y-axis versus time along an x-axis. The graph 600 indicates a change in a trend of the ramping up supply voltage 615 and corresponding change in a trend of the IC output voltage 635 over a period of time in accordance with the method of the present invention for grounding IC outputs 110a-b. The shown graph 600 is not to the scale.

In the shown embodiment, the IC power supply voltage 615 ramps up steadily from zero volts (0 V) to the target voltage 630 in a span of time. The span of time may vary from one hundred microseconds (100 μs) to two seconds (2 s).

The ramping up IC power supply voltage 615 from zero volts (0 V) to the target voltage 630 is further shown crossing the base voltage 620 and the minimum working voltage 625 before achieving the target voltage 630. The IC power supply voltage 615 is shown constant at the target voltage 630 for rest period of time.

In addition, the IC output voltage 635 is shown ramping up from zero volts (0 V) to a certain first value of IC output voltage 635 over a first span of time 640. The first span of time 640 may be equal to a time interval in which the ramping up IC power supply voltage 615 becomes greater than the base voltage 620.

When IC power supply voltage 615 is greater than the base voltage 620, the first switching module 125a turns on 510 and connects 515 the IC outputs 110a-b to the common ground 130. Accordingly, the IC output voltage 635 is also shown to ramp down from the certain first value of IC output voltage 635 to zero volts (0 V) or near zero volts (0 V) over a second span of time 645. The second span of time 645 may be equal to a time interval in which the first switching module 125a turns on 510 and connects 515 the IC outputs 110a-b to the common ground 130.

The IC output voltage 635 is further shown constant at zero volts (0 V) for a period of time. At a moment when the IC power supply voltage 615 is greater than the minimum working voltage 625, the IC output voltage 635 is shown ramping up from zero volts (0 V) to the power supply voltage 615 through the pull-up resistors 120a-b. The IC output voltage 635 may achieve the power supply voltage 615 when the IC power voltage 615 equals the target voltage 630.

The present invention provides an apparatus, system, and method for grounding IC outputs. Beneficially, such an apparatus, system, and method would allow grounding IC outputs when an IC is powered on or powered off. The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus to ground outputs, the apparatus comprising:
a first switching module in communication with integrated circuit (IC) outputs and a common ground and configured to turn on and connect the IC outputs to the common ground when an IC power supply voltage exceeds a base voltage, wherein the IC outputs are configured to be pulled up to the IC power supply voltage through pull-up resistors when a first voltage is driven lower than the base voltage; and
a second switching module configured to turn off the first switching module, disconnect the IC outputs from the common ground, and pull the IC outputs up to the IC power supply voltage when the IC power supply voltage exceeds a minimum working voltage.

2. The apparatus of claim 1, wherein the first switching module comprises a first voltage divider in communication with the IC power supply and the common ground and yielding the first voltage that is a specified fraction of the IC power supply voltage at a first divider output and a low voltage first Field Effect Transistor (FET) with a source in communication with the IC outputs and with the IC power supply through a first resistor, a drain in communication with the common ground, and a gate in communication with the first divider output wherein the first FET turns on when the first voltage exceeds the base voltage.

3. The apparatus of claim 2, wherein the second switching module comprises a second voltage divider in communication with the IC power supply and the common ground and yielding a second voltage that is a specified fraction of the power supply voltage at a second divider output and a low voltage second FET with a source in communication with the IC power supply through a second resistor and in further communication with the gate of the first FET through a diode, a drain in communication with the common ground, and a gate in communication with the second voltage divider output wherein the second FET turns on when the second voltage exceeds the minimum working voltage and turns off the first switching module.

4. The apparatus of claim 1, wherein the base voltage is in the range of 1% to 5% of a nominal power supply voltage.

5. The apparatus of claim 1, wherein the minimum voltage is in the range of 85% to 95% of a nominal power supply voltage.

6. The apparatus of claim 1, wherein the first and second switching modules comprise semiconductor structures integrated in a semiconductor device.

7. The apparatus of claim 1, wherein a nominal power supply voltage is in the range of −10% to +10% of a target voltage selected from 1.0 volts, 1.8 volts, and 3.3 volts.

8. The apparatus of claim 7, wherein the nominal power supply voltage is in the range of −5% to +5% of the target voltage selected from 1.0 volts, 1.8 volts, and 3.3 volts.

9. A method for grounding outputs, the method comprising:
turning on a first switching module in communication with IC outputs and a common ground when an IC power supply voltage exceeds a base voltage, wherein the IC outputs are configured to be pulled up to the IC power supply voltage through pull-up resistors when a first voltage is driven lower than the base voltage;
connecting the IC outputs to the common ground;
turning on a second switching module when the IC power supply voltage exceeds a minimum working voltage;
turning off the first switching module; and
disconnecting the IC outputs from the common ground and pulling the IC outputs up to the IC power supply voltage.

10. The method of claim 9, where the first switching module comprises a first voltage divider in communication with the IC power supply and the common ground and yielding the first voltage that is a specified fraction of the IC power supply voltage at a first divider output and a low voltage first FET with a source in communication with the IC outputs and with the IC power supply through a first resistor, a drain in communication with the common ground, and a gate in communication with the first divider output wherein the first FET turns on when the first voltage exceeds the base voltage.

11. The method of claim 10, where the second switching module comprises a second voltage divider in communication with the IC power supply and the common ground and yielding a second voltage that is a specified fraction of the IC power supply voltage at a second divider output and a low voltage second FET with a source in communication with the power supply through a second resistor and in further communication with the gate of the first FET through a diode, a drain in communication with the common ground, and a gate in communication with the second voltage divider output wherein the second FET turns on when the second voltage exceeds the minimum working voltage and turns off the first switching module.

12. The method of claim 9, wherein the base voltage is in the range of 1% to 5% of a nominal power supply voltage.

13. The method of claim 9, wherein the minimum voltage is in the range of 85% to 95% of a nominal power supply voltage.

14. A system to ground outputs, the system comprising:
an IC power supply;
a plurality of IC outputs;
a common ground;
a first switching module in communication with the IC outputs and the common ground and configured to turn on and connect the IC outputs to the common ground when the IC power supply voltage exceeds a base voltage, wherein the IC outputs are configured to be pulled up to the IC power supply voltage through pull-up resistors when a first voltage is driven lower than the base voltage, the first switching module further comprising a first voltage divider in communication with the IC power supply and the common ground and yielding the first voltage that is a specified fraction of the IC power supply voltage at a first divider output and a low voltage first FET with a source in communication with the IC outputs and with the IC power supply through a first resistor, a drain in communication with the common ground, and a gate in communication with the first divider output wherein the first FET turns on when the first voltage exceeds the base voltage; and
a second switching module configured to turn off the first switching module, disconnect the IC outputs from the common ground and pull the IC outputs up to the IC power supply voltage when the IC power supply voltage exceeds a minimum working voltage.

15. The system of claim 14, wherein the second switching module comprises a second voltage divider in communication with the IC power supply and the common ground and yielding a second voltage that is a specified fraction of the power supply voltage at a second divider output and a low voltage second FET with a source in communication with the IC power supply through a second resistor and in further communication with the gate of the first FET through a diode, a drain in communication with the common ground, and a gate in communication with the second voltage divider output wherein the second FET turns on when the second voltage exceeds the minimum working voltage and turns off the first switching module.

16. The system of claim 14, wherein the first and second switching modules comprise semiconductor structures integrated in a semiconductor device.

17. The system of claim 14, wherein a nominal power supply voltage is in the range of −10% to +10% of a target voltage selected from 1.0 volts, 1.8 volts, and 3.3 volts.

18. The system of claim 14, wherein a nominal power supply voltage is in the range of −5% to +5% of a target voltage selected from 1.0 volts, 1.8 volts, and 3.3 volts.

19. An article of manufacture for grounding outputs, the article comprising:
a first switching module in communication with IC outputs and a common ground and configured to turn on and connect the IC outputs to the common ground when an power supply voltage exceeds a base voltage, wherein the IC outputs are configured to be pulled up to the power supply voltage through respective pull-up resistors when a first voltage is driven lower than the base voltage and the first switching module further comprises a first voltage divider in communication with the IC power supply and the common ground and yielding the first voltage that is a specified fraction of the power supply voltage at a first divider output and a low voltage first FET with a source in communication with the IC outputs and with the IC power supply through a first resistor, a drain in communication with the common ground, and a gate in communication with the first divider output wherein the first FET turns on when the first voltage exceeds the base voltage; and
a second switching module configured to turn off the first switching module, disconnect the IC outputs from the common ground, and pull the IC outputs up to the IC power supply voltage when the power supply voltage exceeds a minimum working voltage, the second switching module further comprising a second voltage divider in communication with the IC power supply and the common ground and yielding a second voltage that is a specified fraction of the power supply voltage at a second divider output and a low voltage second FET with a source in communication with the IC power supply through a second resistor and in further communication with the gate of the first FET through a diode, a drain in communication with the common ground, and a gate in communication with the second voltage divider output wherein the second FET turns on when the second voltage exceeds the minimum working voltage and turns off the first switching module.

20. The apparatus of claim 1, wherein the base voltage is in the range of 1% to 5% of a nominal power supply voltage and the minimum voltage is in the range of 85% to 95% of the nominal power supply voltage.
